(19) United States
(12) Patent Application Publication
(10) Pub. No.: US 2026/0337809 A1
(43) Pub. Date: Oct. 29, 2026

(54) ELECTRODE AND USE THEREOF

(71) Applicant: Magneto Special Anodes (Suzhou) Co., Ltd., Suzhou (CN)

(72) Inventors: Junwei XUE, Suzhou (CN); Hongyuan CHEN, Suzhou (CN)

(21) Appl. No.: 19/116,197

(22) PCT Filed: Oct. 2, 2022
(86) PCT No.: PCT/CN2022/123677

§ 371 Date: Mar. 27, 2025

(51) Int. Cl. C25D 17/10; C25D 3/38; H05K 3/18

(52) U.S. Cl. CPC C25D 17/10; C25D 3/38; H05K 3/188; H05K 2203/0723

(57) ABSTRACT

An electrode includes a substrate, a catalytic layer, and a protective layer. The catalytic layer is selected from a mixed metal oxide layer, and the protective layer is selected from an organic ionomer layer. A surface coating may further be included between the catalytic layer and the protective layer; and an interlayer may further be included between the substrate and the catalytic layer. The electrode may be used as an anode for a surface processing application.

### TECHNICAL FIELD

The present application relates to, but is not limited to, the field of electrochemistry, and specifically relates to, but is not limited to, an electrode and use thereof.

### BACKGROUND OF THE RELATED ART

A printed circuit board is a main component of an electronic device, and is widely used as a connection carrier for integrated electronics and other devices. Electroplating, for example, vertical conveyor plating (VCP), is a common method for the preparation of a printed circuit board.

In the application of VCP of copper for a printed circuit board, a metal electrode with a mixed metal oxide (MMO) coating is conventionally used as an anode, and additives are usually required, such as carriers, brighteners and leveling agents, which may achieve fine grains, non-directional copper grain structures and a uniform copper thickness. In this case, for the MMO coated anode, contact of metal (e.g., Ir) active sites with additive molecules needs to be prevented, in order to avoid additive consumption. Compared with a Cu—P alloy anode, the MMO coated anode has a much higher additive consumption rate.

### SUMMARY

The following is a summary of the subject matter described in detail herein. This summary is not intended to limit the protection scope of the claims.

In order to reduce the additive consumption rate and reduce the production cost, the inventors of the present application have made improvements to the MMO coated electrode through years of careful research.

The present application provides an electrode, including a substrate, a catalytic layer and a protective layer; wherein the catalytic layer may be selected from a mixed metal oxide layer; and the protective layer may be selected from an organic ionomer layer, e.g., may be selected from a fluororesin layer, e.g., may be a sulfonated tetrafluoroethylene layer, e.g., may be Nafion.

In some embodiments, a surface coating may further be included between the catalytic layer and the protective layer, and the surface coating may be selected from a Ta oxide layer, e.g., may be a Ta₂O₅ layer.

In some embodiments, an interlayer may further be included between the substrate and the catalytic layer, and the interlayer may be selected from a Ta oxide layer, a Ti oxide layer, a Ti—Ta mixed metal oxide layer, a Ti—Ta alloy layer or a Ti—Pd alloy layer.

In some embodiments, the catalytic layer and the surface coating may be alternately stacked multiple layers.

In some embodiments, a loading amount of the protective layer may be from 1 g/m² to 10 g/m², and may also be from 2 g/m² to 5 g/m².

In some embodiments, a Ta content in the surface coating may be from 1 g/m² to 20 g/m², and may also be from 10 g/m² to 15 g/m².

In some embodiments, the catalytic layer may be selected from a Ru—Ti mixed metal oxide layer, an Ir—Ti mixed metal oxide layer, a Ru—Ir—Ti mixed metal oxide layer, a Ru—Ta mixed metal oxide layer, an Ir—Ta mixed metal oxide layer, a Ru—Ir—Ta mixed metal oxide layer, or a Pt—Ir mixed metal oxide layer.

In some embodiments, a content of Ti, Ta or Pt in the catalytic layer may be from 10 wt % to 80 wt %, and may also be from 20 wt % to 70 wt %, of the total mass of metal elements.

In some embodiments, a loading amount of Ru, Ir or Pt in the catalytic layer may be from 2 g/m² to 20 g/m², may also be from 5 g/m² to 10 g/m², and may also be from 6 g/m² to 8 g/m².

In some embodiments, a Ta content in the interlayer Ti—Ta mixed metal oxide layer may be not less than 10 wt % of the total mass of metal elements, may also be not less than 20 wt % of the total mass of metal elements, and may further be from 40 wt % to 50 wt % of the total mass of metal elements.

In some embodiments, a Ta content in the interlayer Ti—Ta alloy layer may be not less than 10 wt % of a total mass of the alloy, may also be not less than 20 wt % of the total mass of the alloy, and may further be from 40 wt % to 50 wt % of the total mass of the alloy.

In some embodiments, a Pd content in the interlayer Ti—Pd alloy layer may be from 0.01 wt % to 0.25 wt % of the total mass of the alloy, and may also be from 0.12 wt % to 0.25 wt % of the total mass of the alloy.

In some embodiments, a loading amount of Ta in the interlayer Ta oxide layer, the interlayer Ti—Ta mixed metal oxide layer and the interlayer Ti—Ta alloy layer may be from 1 g/m² to 10 g/m², and may also be 4 g/m² or 5 g/m².

In some embodiments, a loading amount of Ti in the interlayer Ti oxide layer and the interlayer Ti—Pd alloy layer may be from 1 g/m² to 10 g/m², and may also be 4 g/m² or 5 g/m².

In some embodiments, the substrate may be selected from metal Ti, Ta, Nb or an alloy thereof.

The present application further provides use of the electrode described above, wherein the electrode may be used as an anode for a surface processing application, may also be used as an anode for plating, and may further be used as an anode for copper plating or as an anode for vertical conveyor plating.

In some embodiments, the plating may be used for preparing a printed circuit board.

Other features and the advantages of the present application will be set forth in the following description. Other advantages of the present application may be realized and obtained by the solutions described in the description and the drawings. Other aspects will become apparent upon reading and understanding the accompanying drawings and the detailed description.

### BRIEF DESCRIPTION OF THE DRAWINGS

The accompanying drawings are used to provide an understanding of the technical solutions of the present application, and constitute a part of the specification. They are used to explain the technical solutions of the present application together with the examples of the present application, and do not constitute a limitation to the technical solutions of the present application.

FIG. 1 is a scanning electron microscopy picture of the substrate titanium mesh of the electrode prepared in Example 1;

FIG. 2 is a scanning electron microscopy picture of a top view of a protective layer of the electrode prepared in Example 1.

### DETAILED DESCRIPTION

Examples of the present application will be described in detail below in conjunction with the drawings. It should be noted that the examples in the present application and the features in the examples may be arbitrarily combined with each other provided that there is no conflict.

An example of the present application provides an electrode, for example, the electrode includes a substrate, a catalytic layer and a protective layer which are sequentially stacked from bottom to top. The protective layer can effectively prevent the contact between additive molecules and metal active sites, and exhibit chemical inertia in the oxygen evolution process, greatly reducing the additive consumption rate.

It is also feasible to symmetrically arrange the catalytic layer and the protective layer on both sides of the substrate, or arrange the catalytic layer and the protective layer on one side of the substrate and arrange only the catalytic layer on the other side of the substrate. The catalytic layer provides electrochemical activity for an oxygen evolution reaction and has the properties such as resistance to wear and catalyst corrosion stability.

A surface coating may or may not be provided between the catalytic layer and the protective layer. The surface coating can provide a better interface for adhesion of the protective layer, improving the bonding of the protective layer to the catalytic layer.

An interlayer may or may not be provided between the substrate and the catalytic layer. The interlayer has good corrosion resistance and can provide additional corrosion protection for the substrate.

The catalytic layer and the surface coating may be alternately stacked multiple layers.

The substrate may be selected from metals Ti, Ta, Nb or an alloy thereof. For example, it may be metal titanium (Ti); may also be industrial pure titanium (e.g., ASTM Grade 1 or ASTM Grade 2 industrial pure titanium); and may further be a Ti-based alloy (e.g., ASTM Grade 7 or ASTM Grade 11 titanium alloy), e.g., a Ti—Nb alloy containing a small amount of Nb, a Ti—Ta alloy containing a small amount of Ta, or a Ti—Nb—Ta alloy containing a small amount of Nb and Ta, for example, the total content of Nb and Ta does not exceed 5 wt % of the total mass of the alloy. The substrate may be a mesh, a plate, a foam, a felt, etc., e.g. may be a metal titanium mesh.

The interlayer may be selected from a Ta oxide, a Ti oxide, a Ti—Ta mixed metal oxide, a Ti—Ta alloy or a Ti—Pd alloy. The Ta content in the Ti—Ta mixed metal oxide layer may be not less than 10 wt % of the total mass of metal elements, may also be not less than 20 wt % of the total mass of metal elements, and may further be from 40 wt % to 50 wt % of the total mass of metal elements. For example, the mass ratio of Ta to Ti may be 40:60, 50:50, etc. The Ta content in the Ti—Ta alloy may be not less than 10 wt % of the total mass of the alloy, may also be not less than 20 wt % of the total mass of the alloy, and may further be from 40 wt % to 50 wt % of the total mass of the alloy. For example, the mass ratio of Ta to Ti may be 40:60, 50:50, etc. The Pd content in the Ti—Pd alloy layer may be from 0.01 wt % to 0.25 wt % of the total mass of the alloy, and may also be from 0.12 wt % to 0.25 wt % of the total mass of the alloy. For example, the Pd content may be 0.15 wt %, 0.18 wt %, 0.20 wt %, etc. The loading amount of Ta in the Ta oxide layer, the Ti—Ta mixed metal oxide layer and the Ti—Ta alloy layer may be from 1 g/m² to 10 g/m², e.g., 4 g/m², 5 g/m², etc. The loading amount of Ti in the Ti oxide layer and the Ti—Pd alloy layer may be from 1 g/m² to 10 g/m², e.g., 4 g/m² or 5 g/m²; or the loading amount of Pd in the Ti—Pd alloy layer may be from 0.1 mg/m² to 25 mg/m², e.g., 1 mg/m², 5 mg/m², 10 mg/m², 15 mg/m², etc.

The interlayer may be prepared by a wet-chemical method or a vapor deposition method, e.g., a magnetron sputtering method, a chemical vapor deposition method, etc. The use of the magnetron sputtering method can enable the formation of a dense interlayer on the substrate, which improves the corrosion resistance.

In an example of the magnetron sputtering process, the temperature of the substrate is controlled to from 200 °C to 400 °C, an inert gas is used as a sputtering gas, a vacuum degree is from 0.1 Pa to 0.5 Pa, the power of a DC power supply is from 100 W to 500 W, a target-substrate distance is from 30 mm to 100 mm, and a required loading amount is obtained by controlling the ratio of simultaneously used target materials and adjusting the sputtering time.

The catalytic layer may be selected from a Ru—Ti mixed metal oxide layer, an Ir—Ti mixed metal oxide layer, a Ru—Ir—Ti mixed metal oxide layer, a Ru—Ta mixed metal oxide layer, an Ir—Ta mixed metal oxide layer, a Ru—Ir—Ta mixed metal oxide layer, or a Pt—Ir mixed metal oxide layer. The content of Ti, Ta or Pt in the catalytic layer may be from 10 wt % to 80 wt %, and may also be from 20 wt % to 70 wt %, e.g., 30 wt %, 40 wt %, 50 wt %, 60 wt %, etc, of the total mass of metal elements. The loading amount of Ru, Ir or Pt in the catalytic layer may be from 2 g/m² to 20 g/m², may also be from 5 g/m² to 10 g/m², and may also be from 6 g/m² to 8 g/m², e.g., 7 g/m² etc. The catalytic layer provides electrochemical activity for an oxygen evolution reaction and has the properties such as resistance to wear and catalyst corrosion stability.

The catalytic layer may be prepared by methods such as coating-thermal decomposition, chemical vapor deposition (e.g., atomic layer deposition (ALD)), plasma-thermal spray, and physical vapor deposition. In an example of coating-thermal decomposition, the catalytic layer is formed by coating a coating solution, e.g., containing Ru and Ti, containing Ir and Ti, containing Ru, Ir and Ti, containing Ru and Ta, containing Ir and Ta, containing Ru, Ir and Ta, or containing Pt and Ir on the surface of the substrate or the interlayer, followed by drying and thermal decomposition. The coating-thermal decomposition process may be performed several times until a desired loading amount is obtained.

The surface coating may be an oxide of tantalum, which, for example, may be Ta₂O₅. The Ta content in the surface coating may be from 1 g/m² to 20 g/m², and may also be from 10 g/m² to 15 g/m², e.g., 11 g/m², 12 g/m², 13 g/m², 14 g/m², etc.

The surface coating may be prepared by methods such as coating-thermal decomposition, chemical vapor deposition (e.g., ALD), plasma-thermal spray, and physical vapor deposition. In an example of coating-thermal decomposition, the surface coating is formed by coating a coating solution containing Ta on the surface of the catalytic layer, followed by drying and thermal decomposition. The coating-thermal decomposition process may be performed several times until a desired loading amount is obtained.

The protective layer may be an organic ionomer, e.g., may be fluororesin, e.g., may also be sulfonated tetrafluoroethylene, e.g., may further be Nafion. The loading amount of the protective layer may be from 1 g/m² to 10 g/m², and may also be from 2 g/m² to 5 g/m², e.g., 3 g/m², 4 g/m², etc.

The protective layer may be prepared by methods such as coating-thermal decomposition, chemical vapor deposition (e.g., ALD), plasma-thermal spray, and physical vapor deposition.

The electrode of the present application is suitable for use as an anode for plating, especially as an anode for copper plating or as an anode for vertical conveyor plating, for preparation of a printed circuit board.

The present application has the following beneficial effects:
1. The electrode of the present application has a dense protective layer (for example, a fluororesin layer), which can effectively prevent the contact between additive molecules and metal active sites, and exhibit chemical inertia in the oxygen evolution process, greatly reducing the additive consumption rate.
2. The protective layer of the present application may also provide ionic conductivity, thus reducing the resistance of the coating to ionic current.
3. The combination of the protective layer and the surface coating (for example, a Ta₂O₅ layer) in the electrode of the present application achieves a synergistic effect, enabling better adhesion of the protective layer to the surface coating, which is more beneficial to the reduction in the additive consumption rate.
4. The electrode of the present application has a simple preparation process and a reduced production cost, which is beneficial to large-scale production.

### Example 1

Metal titanium (Ti) was used as an electrode substrate. A 2 mm thick titanium mesh, with a grid factor of 2.0 and meeting the requirement of ASTM-B265 Grade 1 was selected, and was then sandblasted with iron sand and pickled with sulfuric acid.

An Ir—Ta MMO catalytic layer was formed on the substrate, wherein the loading amount of Ir was 5 g/m². A chloroiridium acid aqueous solution and a tantalum pentachloride salt were used to formulate an n-butanol solution with an iridium mass concentration of 3 wt %, in which the mass ratio of iridium element to tantalum element was 65:35. The solution was applied to the surface of the substrate with a brush. Each time when 1 g iridium was applied per square meter of coating, the substrate was dried at 80 °C and decomposed at 500 °C for 10 minutes, and then it was taken out for cooling and continued to be coated until the iridium loading target of 5 g/m² was reached.

A Ta₂O₅ surface coating was formed on the catalytic layer, wherein the loading amount of Ta was 10 g/m². A tantalum pentachloride salt was used to formulate an n-butanol solution with a tantalum mass concentration of 3 wt %. The solution was applied to the surface of the catalytic layer with a brush. Each time when 1 g tantalum was applied per square meter of coating, the object was dried at 80 °C and decomposed at 500 °C for 10 minutes, and then it was taken out for cooling and continued to be coated until the tantalum loading target of 10 g/m² was reached.

A fluororesin protective layer was formed on the surface coating, wherein the loading amount of fluororesin was 2 g/m². An isopropanol solution containing 5 wt % Nafion was formulated. The solution was applied to the surface of the surface coating with a brush. Each time when 1 g fluororesin was applied per square meter of coating, the object was cured, and then it was taken out for cooling and continued to be coated until the fluororesin loading amount of 2 g/m² was reached.

An electrode was thus prepared.

### Example 2

The same metal titanium (Ti) as in Example 1 was used as an electrode substrate.

The same steps as in Example 1 were used to form an Ir—Ta MMO catalytic layer on the substrate, wherein the loading amount of Ir was 5 g/m².

The same steps as in Example 1 were used to form a fluororesin protective layer on the catalytic layer, wherein the loading amount of fluororesin was 5 g/m².

An electrode was thus prepared.

### Example 3

The same metal titanium (Ti) as in Example 1 was used as an electrode substrate.

The same steps as in Example 1 were used to form an Ir—Ta MMO catalytic layer on the substrate, wherein the loading amount of Ir was 5 g/m².

The same steps as in Example 1 were used to form a Ta₂O₅ surface coating on the catalytic layer, wherein the loading amount of Ta was 1 g/m².

The same steps as in Example 1 were used to form a second Ir—Ta MMO catalytic layer on the surface coating, wherein the loading amount of Ir was 1 g/m².

The same steps as in Example 1 were used to form a second Ta₂O₅ surface coating on the second catalytic layer, wherein the loading amount of Ta was 10 g/m².

The same steps as in Example 1 were used to form a fluororesin protective layer on the second surface coating, wherein the loading amount of fluororesin was 5 g/m².

An electrode was thus prepared.

### Comparative Example 1

The same metal titanium (Ti) as in Example 1 was used as an electrode substrate.

The same steps as in Example 1 were used to form an Ir—Ta MMO catalytic layer on the substrate, wherein the loading amount of Ir was 5 g/m².

An electrode was thus prepared.

### Comparative Example 2

The same metal titanium (Ti) as in Example 1 was used as an electrode substrate.

The same steps as in Example 1 were used to form an Ir—Ta MMO catalytic layer on the substrate, wherein the loading amount of Ir was 5 g/m².

The same steps as in Example 1 were used to form a Ta₂O₅ surface coating on the catalytic layer, wherein the loading amount of Ta was 10 g/m².

An electrode was thus prepared.

### Electrode Microstructure

The electrode prepared in Example 1 was tested by scanning electron microscopy.

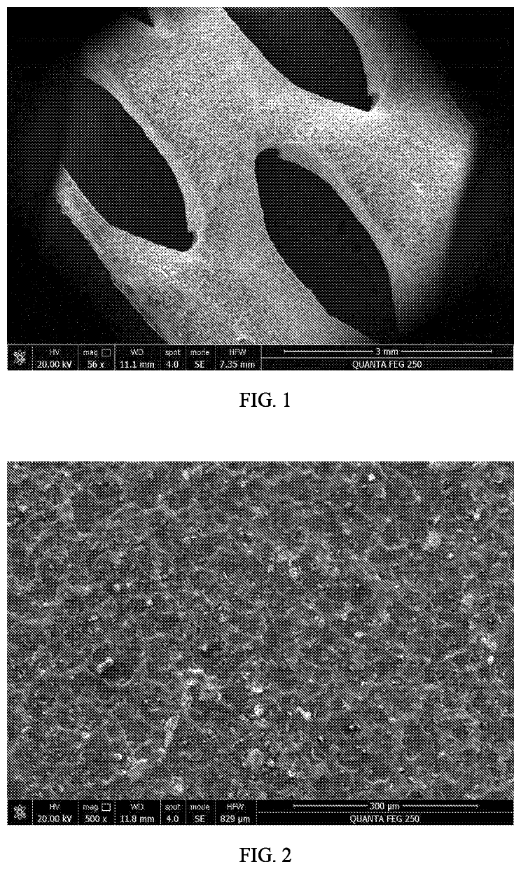

The substrate of the electrode is shown in FIG. 1, and the substrate is grid shaped.

The protective layer of the electrode is shown in FIG. 2. As can be seen from FIG. 2, the protective layer is a dense structure. The dense protective layer can effectively prevent the contact between additive molecules and metal active sites, and exhibit chemical inertia in an oxygen evolution process, greatly reducing the additive consumption rate.

### Test of Additive Consumption Rate

The electrodes obtained in the examples and comparative examples were tested for additive consumption rate. The test results are shown in Table 1:

TABLE 1
Additive consumption rate

| | | | | Additive | |
|---|---|---|---|---|---|
| | | | | consumption | |
| | Catalytic layer | Surface coating | Protective layer | rate (EVF-B) | |
| Example 1 | Ir—Ta MMO, Ir:Ta = 65:35, | Ta₂O₅, Ta loading | Fluororesin, loading | 126 | mL/KAh |
| | Ir loading amount 5 g/m² | amount 10 g/m² | amount 2 g/m² | | |
| Example 2 | Ir—Ta MMO, Ir:Ta = 65:35, | None | Fluororesin, loading | 153 | mL/KAh |
| | Ir loading amount 5 g/m² | | amount 5 g/m² | | |
| Example 3 | 1) Ir—Ta MMO, Ir:Ta = 65:35, Ir | | Fluororesin, loading | 78 | mL/KAh |
| | loading amount 5 g/m²; | | amount 5 g/m² | | |
| | 2) Ta₂O₅, Ta loading amount 1 g/m²; | | | | |
| | 3) Ir—Ta MMO, Ir:Ta = 65:35, Ir loading | | | | |
| | amount 1 g/m²; | | | | |
| | 4) Ta₂O₅, Ta loading amount 10 g/m². | | | | |
| Comparative | Ir—Ta MMO, Ir:Ta = 65:35, | None | None | 767 | mL/KAh |
| example 1 | Ir loading amount 5 g/m² | | | | |
| Comparative | Ir—Ta MMO, Ir:Ta = 65:35, | Ta₂O₅, Ta loading | None | 273 | mL/KAh |

| | | |
|---|---|---|
| example 2 | Ir loading amount 5 g/m² | amount 10 g/m² |

Note: “EVF-B” is an additive used for continuous copper plating in manufacturing of a printed circuit board.

As can be seen from Table 1, the additive consumption rates of the electrodes (having a fluororesin protective layer) in Examples 1-3 of the present application are lower than the additive consumption rates of the electrodes (excluding a fluororesin protective layer) in Comparative examples 1-2, and in particular, the additive consumption rate in Example 3 is only 78 mL/KAh, which is about one tenth of that in Comparative example 1. The main reason is that fluororesin is denser, which can effectively prevent contact between additive molecules and Ir active sites, and exhibits chemical inertia in the oxygen evolution process.

In addition, in Example 2 of the present application, the additive consumption rate can still be effectively reduced in the case of excluding the surface coating and including only the fluororesin protective layer. Thus, it can be seen that the fluororesin protective layer is a key factor in reducing the additive consumption rate.

Moreover, even in the case where the loading amount of fluororesin in Example 1 is smaller than that in Example 2, the additive consumption rate in Example 1 is still lower than that in Example 2. The main reason is that the combination of the surface coating Ta₂O₅ and the protective layer fluororesin produces a synergistic effect, and they can be combined better, which is more favorable to the reduction of the additive consumption rate.

As can be further seen from Table 1, the additive consumption rate in Example 3 is even lower, which indicates that alternately stacking the MMO layers and the surface coatings can achieve a better effect in reducing the additive consumption rate.

Although the embodiments disclosed in the present application are as above, the contents described are only the embodiments adopted for the convenience of understanding the present application, and are not used to limit the present application. Any person skilled in the field to which the present application belongs can make any modifications and changes in the implementation form and details without departing from the spirit and scope disclosed by the present application, but the scope of patent protection of the present application shall still be subject to the scope defined by the appended claims.

1. An electrode, comprising:
a substrate;
a catalytic layer; and
a protective layer;
wherein the catalytic layer comprises a mixed metal oxide layer; and
the protective layer comprises an organic ionomer layer.

2. The electrode according to claim 1, further comprising a surface coating between the catalytic layer and the protective layer, the surface coating comprising a Ta oxide layer.

3. The electrode according to claim 1, further comprising an interlayer between the substrate and the catalytic layer, the interlayer being selected from the group consisting of a Ta oxide layer, a Ti oxide layer, a Ti—Ta mixed metal oxide layer, a Ti—Ta alloy layer, and a Ti—Pd alloy layer.

4. The electrode according to claim 2, wherein the catalytic layer and the surface coating are alternately stacked multiple layers.

5. The electrode according to claim 1, wherein a loading amount of the protective layer is from 1 g/m² to 10 g/m².

6. The electrode according to claim 2, wherein a Ta content in the surface coating is from 1 g/m² to 20 g/m².

7. The electrode according to claim 1, wherein the catalytic layer is selected from the group consisting of a Ru—Ti mixed metal oxide layer, an Ir—Ti mixed metal oxide layer, a Ru—Ir—Ti mixed metal oxide layer, a Ru—Ta mixed metal oxide layer, an Ir—Ta mixed metal oxide layer, a Ru—Ir—Ta mixed metal oxide layer, and a Pt—Ir mixed metal oxide layer.

8. The electrode according to claim 7, wherein a content of Ti, Ta, or Pt in the catalytic layer is from 10 wt % to 80 wt % of a total mass of metal elements.

9. The electrode according to claim 7, wherein a loading amount of Ru, Ir, or Pt in the catalytic layer is from 2 g/m² to 20 g/m².

10. The electrode according to claim 3, wherein a Ta content in the interlayer Ti—Ta mixed metal oxide layer is not less than 10 wt % of a total mass of metal elements.

11. The electrode according to claim 3, wherein a loading amount of Ta in the interlayer Ta oxide layer, the interlayer Ti—Ta mixed metal oxide layer, and the interlayer Ti—Ta alloy layer is from 1 g/m² to 10 g/m².

12. The electrode according to claim 1, wherein the substrate comprises metal Ti, Ta, Nb, or an alloy comprising metal Ti, Ta, or Nb.

13. An anode configured to be used in a surface processing application, wherein the electrode comprises the electrode of claim 1.

14. The anode according to claim 13, wherein the anode is configured to conduct plating for preparing a printed circuit board.

15. The electrode of claim 1, wherein the protective layer comprises a fluororesin layer.

16. The electrode of claim 1, wherein the protective layer comprises a sulfonated tetrafluoroethylene layer.

17. The electrode according to claim 3, wherein a Ta content in the interlayer Ti—Ta alloy layer is not less than 10 wt % of a total mass of the alloy.

18. The electrode according to claim 3, wherein a Pd content in the interlayer Ti—Pd alloy is from 0.01 wt % to 0.25 wt % of a total mass of the alloy.

19. The electrode according to claim 3, wherein a loading amount of Ti in the interlayer Ti oxide layer and the interlayer Ti—Pd alloy layer is from 1 g/m² to 10 g/m².
